(19) United States
(12) Patent Application Publication
(10) Pub. No.: US 2019/0172526 A1
(43) Pub. Date: Jun. 6, 2019

(54) SRAM MEMORY HAVING A FAST CLEAR

(71) Applicant: COMMISSARIAT A L'ENERGIE ATOMIQUE ET AUX ENERGIES ALTERNATIVES, Paris (FR)

(72) Inventors: Jean-Philippe Noel, Grenoble (FR); Noemie Boher, Delft (NL); Romain Wacquez, Marseille (FR)

(73) Assignee: COMMISSARIAT A L'ENERGIE ATOMIQUE ET AUX ENERGIES ALTERNATIVES, Paris (FR)

(21) Appl. No.: 16/210,663

(22) Filed: Dec. 5, 2018

(30) Foreign Application Priority Data
Dec. 6, 2017 (FR) 17 61692

(51) Int. Cl. G11C 11/419; G11C 11/417; G11C 11/418; G11C 11/412

(52) U.S. Cl. CPC G11C 11/419; G11C 11/412; G11C 11/418; G11C 11/417

(57) ABSTRACT

Static random access memory device comprising a memory matrix provided with at least one column (COL₁) formed from a plurality of SRAM memory cells (C₁₁, C_{N1}), the device being provided with a fast erase memory circuit configured to connect a first bit line (BL_{T}) and a second bit line (BL_{F}) shared by cells in said column, following reception of an erase signal (ERASE).

### TECHNICAL DOMAIN AND PRIOR ART

This invention relates to the field of SRAM (Static Random Access Memory) type memories, and in particular relates to the field of using countermeasures to prevent unauthorised access to information stored in a matrix of SRAM memory cells.

This invention makes use of a circuit for making a fast erase of data memorised in an SRAM memory.

### PRIOR ART

The function of an SRAM memory is to store volatile information, some of which may be confidential and/or secured. A conventional method of protecting some data contained in a memory device, for example an encryption key, and to prevent an unauthorised third party from accessing them, is to erase the content of this information that is stored by memory cells when a fraudulent access attempt is detected.

One method of erasing a volatile memory is simply to cut off the power supply to the volatile memory when an unauthorised access or access attempt is detected.

In this case, the erase time is directly related to the electrical capacitance of the power supply lines to the memory plane that are typically arranged in the form of a power supply grid. However, the electrical capacitance of such a power supply grid can be up to several tens of pF and the discharge time can be significant, of the order or a microsecond, or even a millisecond depending on temperature conditions.

One solution to mitigate a problem of slowness in erasing the memory is to provide devices comprising diodes to quickly evacuate charges. Nevertheless, although this type of device is effective, it occupies extra surface area.

Document U.S. Pat. No. 8,885,429ºB1 relates to an SRAM memory provided with an erase memory circuit configured to perform a forced write operation by imposing a given logical value on a set of cells.

One particular disadvantage of such as erase operation is that it requires access to a large energy budget and that it can be relatively slow to implement.

This application aims to find a new type of circuit to erase data contained in a SRAM that is better with regard to the disadvantages mentioned above.

### PRESENTATION OF THE INVENTION

This invention aims to implement a countermeasure to prevent unauthorised access that is can quickly, entirely and irreversibly erase the content of SRAM cells in a matrix of SRAM cells.

To achieve this, one embodiment of this invention uses a static random access memory device comprising a memory matrix provided with at least one column formed from a plurality of SRAM memory cells, each of said cells comprising:
a first logical information storage node and a second complementary logical information storage node,
a first access transistor to the first storage node and a second access transistor to the second storage node, the first access transistor and the second access transistor being connected to a first bit line and a second bit line respectively, the first bit line and the second bit line being shared by said cells of said column,

the device also comprising an erase memory circuit configured to force conduction of the access transistors of said cells connected to the first bit line and the second bit line and to connect said first bit line and said second bit line to each other, following reception of an erase signal.

The erase mechanism used enables evacuation of electrical charges contained in each of the elementary memory cells independently of the mode (read, write, retention) in which the memory circuit is placed. The nodes of the erased cells are brought to an intermediate potential that is intermediate between the potential corresponding to a ‘0’ logical level and a ‘1’ logical level.

Such a mechanism makes access to erased information particularly difficult, and in particular more difficult than when an erase operation is performed by imposing a given logical state on a set of cells.

The SRAM memory cells in the column receive a power supply potential, for example VDD, from a power supply means comprising one or several power supply lines that can be connected to a power supply circuit of the matrix. Preferably, following reception of the erase signal, the erase circuit can set the power supply line(s) that supply this power supply potential to the memory cells of said column to high impedance or to leave it (them) floating. This particularly advantageous characteristic participates in organizing a very fast evacuation of electrical charges while limiting consumption during the erase process.

According to one embodiment, the erase circuit may be provided with at least one first switching element, such as a first pass-gate, configured to alternately connect together and to disconnect the first bit line and the second bit line, the switching element being controlled by the erase signal and being arranged between one end of said cell column and a portion of a circuit peripheral to said matrix, said peripheral circuit being provided with a read amplifier and/or a write operations driver.

The erase circuit may also be provided with other switching elements, and particularly a second pass-gate and a third pass-gate, controlled by the erase signal, and configured to disconnect the first bit line and the second bit line respectively from said portion of peripheral circuit, following reception of the erase signal.

Thus, during the erase process, the matrix of cells is advantageously isolated from the cells of a peripheral consuming circuit.

The memory matrix may be powered by a power supply circuit capable of outputting a power supply potential VDD to at least one power supply line shared by a plurality of data cells. Advantageously, said erase circuit can then also be provided with a switch element controlled by the fast erase signal and configured to disconnect said power supply line from said power supply circuit, after an erase signal is received.

Thus, the power supply line that connects all memory cells in the column to a power supply at VDD is disconnected or is put in high impedance or is left floating. This power supply line may also be named the virtual power supply line because it is not directly connected to the power supply VDD but this connection is made through a switch element, for example such as a transistor, particularly of the PMOS type.

During the erase process, the memory matrix may be disconnected from its power supply while there is no need to switch the power supply off or to ground it. Other elements peripheral to the matrix can thus be powered during the erase process.

According to one embodiment, said plurality of data cells connected to said power supply line typically belong to said column of cells.

The memory matrix is typically associated with a peripheral controller for management of the read and write process. Advantageously, the erase circuit comprises means or at least one circuit element, integrated into said peripheral controller and provided with an inverter, the means or the circuit element being designed to apply the erase signal and a signal complementary to said erase signal, particularly to one or several switch elements and/or switches of the erase circuit.

The matrix is typically also arranged in rows of one or several SRAM cells, a plurality of word lines being connected to said plurality of SRAM memory cells of said column respectively, each word line when it is activated can be used to select the memory cell(s) of a given row of SRAM cells among said rows of SRAM cells.

According to one possible embodiment, the erase circuit may also comprise activation means or a portion of activation circuit integrated into a line decoder associated with the matrix and configured to simultaneously activate word lines, so as to make a simultaneous selection of said rows of SRAM cells.

Preferably, in addition to short circuiting the bit lines, the fast erase circuit is configured to activate all lines (WL) in the matrix at the same time.

According to one possible embodiment of the erase circuit, the means of activating the word line may comprise a plurality of transistors arranged at different stages of the line decoder, said transistors having a gate electrode controlled by the erase signal.

According to one possible embodiment, the erase circuit may comprise means in the line decoder for outputting a clock signal for dynamic logic gates of the line decoder, these means of delivering the clock signal forming a logical OR between a clock signal internal to the controller and the erase signal ERASE.

Advantageously, the erase circuit may be provided with an end of erase detection stage to generate an end of erase signal indicating the end of an erase operation performed by said erase circuit.

According to one possible embodiment, the end of erase detection stage can be configured to:—detect when a current output from a low power supply line connected to said cells of the matrix drops below a threshold, and subsequent to this passage:
generate the end of erase signal.

The erase circuit may also comprise a stage to control the state of the erase signal ERASE to modify the state of said end of erase signal ERASE following reception of said end of erase signal.

### BRIEF DESCRIPTION OF THE DRAWINGS

This invention will be better understood after reading the description of example embodiments given purely for information and that are in no way limitative, with reference to the appended drawings on which:

FIG. 1, illustrates an example of a static random access memory cell according to prior art that could be included in an SRAM device equipped with a fast data erase circuit according to the invention;

FIG. 2, illustrates one embodiment of a SRAM cells fast erase circuit according to the invention;

FIG. 3 contains an example time diagram illustrating different phases of a process for erasing data stored in SRAM cells and as implemented using an erase circuit according to one embodiment of this invention;

FIG. 4 contains an example time diagram illustrating an erase solely by grounding power supply lines of the matrix, for comparison purposes;

FIG. 5 illustrates an example of a stage for producing an end of erase operation detection signal;

FIG. 6 illustrates an example of an erase signal state control stage to control different elements participating in the fast erase operation;

FIG. 7 illustrates an example sequence of erase and end of erase detection signals that could be produced in a fast erase circuit like that used according to the invention;

Identical, similar or equivalent parts of the different figures have the same numeric references to facilitate the comparison between different figures.

The different parts shown on the figures are not necessarily all at the same scale, to make the figures more easily understandable.

### DETAILED PRESENTATION OF PARTICULAR EMBODIMENTS

A fast erase circuit like that used according to the invention can be included in an SRAM device comprising a memory plane composed of at least one column COL₁ of cells C₁₁, . . . , C_{N1}. Typically, the memory plane is provided with a plurality of lines LIN₁, . . . LIN_{N} and columns COL₁, COL_{M} of cells C₁₁, . . . , C_{NM} SRAM.

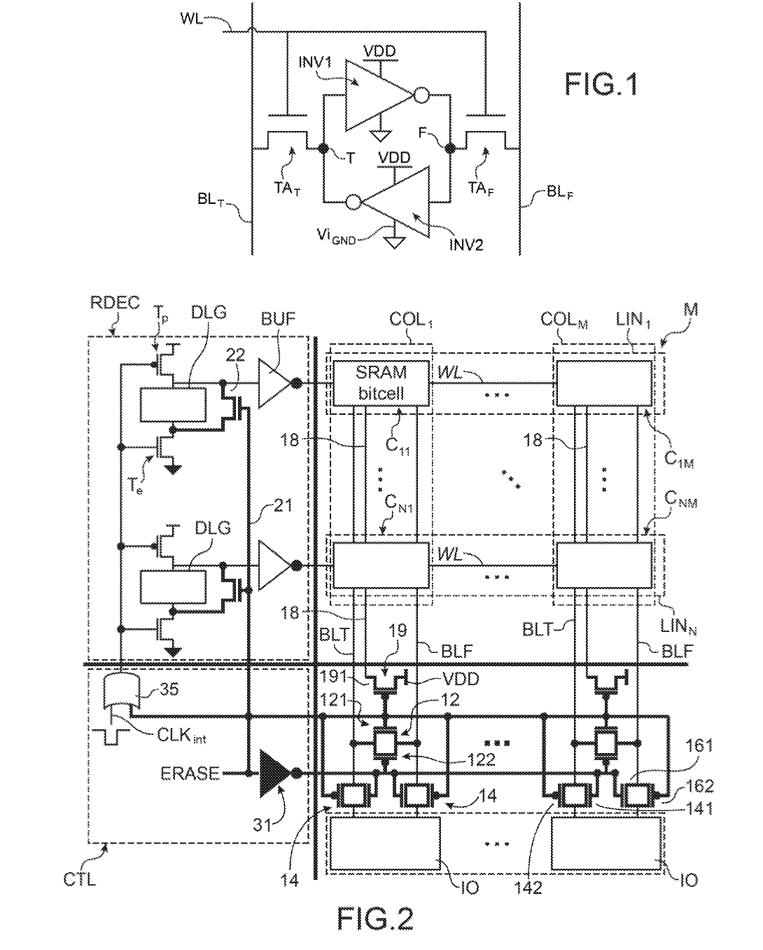

The cells may have a conventional layout as illustrated in FIG. 1. The fast erase circuit can thus be implemented without any modification to the internal structure of SRAM cells and only requires the use of a restricted number of additional elements peripheral to the memory plane. The additional size that can be generated by these additional elements is estimated as being typically less than 5% compared with an equivalent conventional device.

The SRAM cell shown on FIG. 1 is thus provided with two storage nodes T and F, designed to keep first logical information, and logical information complementary to the first information. Logical information is maintained in nodes by transistors forming inverters INV1, INV2 looped back on themselves. For example, when the SRAM cell is of the type commonly named “6T” and is thus formed from 6 transistors, the two inverters INV1, INV2, are typically made by two charge transistors and two conduction transistors. In this example, the inverters INV1, INV2 are powered by a power supply potential VDD. The cell is also connected to a virtual low power supply line, in this case a virtual ground line VirGND, itself connected to a ground line

Access to the storage nodes T and F is made through two access transistors TA_{T} and TA_{F} connected to so-named bit lines BL_{T} and BL_{F} respectively, generally shared by SRAM cells in the same column of cells in the matrix plane.

Access to storage nodes T and F is controlled by a word line WL generally shared by some or all SRAM cells in the same cell line of the hardware plane. The access transistors TA_{T} and TA_{F} are thus designed to enable or to block access to the first node T and the second node F respectively.

An erase circuit is provided located at the periphery of the matrix plane and controlled by an erase signal ERASE, to enable fast erase of logical information stored in such a cell.

The erase signal ERASE may be a logical signal for which a state change is triggered for example by detection of a fraudulent attempt to access information stored in the SRAM. This application does not relate to the manner in which this detection is made. The erase process used is independent of the operating mode (read, write or retention) in which the memory is placed and can be done without switching the power off to elements peripheral to the memory cells matrix.

In this case a cell is erased by activating its access transistors, in other words by making them conducting, particularly by short circuiting the bit lines BL_{T} and BL_{F}, so as to bring the bit lines BL_{T} and BL_{F} to the same potential.

In this case, we no longer distinguish logical levels of the storage nodes T and F respectively, which effectively erases information stored in the cell. Since the bit lines BL_{T} and BL_{F} are shared by some or even all the cells in a given column of the matrix layout, connection of bit lines BL_{T} and BL_{F} enables the evacuation of charges contained in the storage nodes of all cells in this given column. Thus, the cells of an entire column of SRAM cells can thus be erased simultaneously. In this case, all the cells in this column are selected by activating their corresponding access transistors, or making them conducting.

Rather than simultaneously writing replacement information in the cells, the erase solution according to the invention makes it even more difficult to trace the stored information. Furthermore, in order to implement an erase by simultaneous writing of replacement information, the power supply grid would then have to be reinforced to supply the strong current inrush thus generated to assure that this information is correctly written in the entire memory. Such a reinforcement of the power supply grid could then cause a non-negligible additional loss of surface area.

Bit lines BL_{T} and BL_{F} are short circuited by means of a switching element, typically added at the bottom of the column, controlled by the erase signal ERASE.

In the implementation example illustrated on FIG. 2, the switching element 12 is in the form of a “pass-gate” or “transmission-gate”. Such a pass-gate 12 is composed of an N type transistor 121 and a P type transistor 122 with their drains and their sources connected to each other. The gate electrodes of the transistors 121 and 122 are controlled by the erase signal ERASE and a complementary (inverse) signal to this ERASE signal, respectively.

Such a pass-gate 12 thus enables alternative operation with connection of the bit lines BL_{T} and BL_{F} together when it is required to make an erase, and disconnection of the bit lines BL_{T} and BL_{F} from each other during normal operation of the memory plane, in other words during its different read, write and retention modes, depending on the state of the erase signal ERASE.

Several columns of SRAM cells can be erased. Therefore in the illustrated example embodiment, a pass-gate 12 is provided at the base of each of the cell columns. It is thus possible to short circuit all pairs of bit lines BL_{T} and BL_{F} associated with columns of the matrix plane respectively and to do a simultaneous erase using the ERASE signal.

The fast erase circuit is also advantageously configured such that when the bit lines BL_{T} and BL_{F} are short circuited, these bit lines BL_{T} and BL_{F}, are isolated from an element of the IO circuit peripheral to the memory plane and located at one end of the column of cells, generally at the base of the column. This element of the peripheral IO circuit typically comprises a read amplifier (SA for “sense amplifier”) and/or a write operations driver circuit (WR driver).

When erasing, bit lines BL_{T} and BL_{F} of elements that might be powered are thus advantageously disconnected. This participates in a fast evacuation of charges in the cells while protecting the peripheral circuit from the harmful consequences of this evacuation of charges. Apart from the read amplifier, and the write operations driver circuit, the bit lines can be disconnected from a precharge circuit. Thus, bit lines BL_{T} and BL_{F} are isolated from elements that could impose a potential and reduce the rate at which bit lines are brought to the same potential.

Additional switching elements 14 and 16 are thus provided to isolate bit lines BL_{T} and BL_{F}. In the example illustrated, these other switching elements 14 and 16 are in the form of pass-gates or transmission-gates 14, 16 respectively. A pass-gate 14 located between a first bit line BL_{T} and an element of the peripheral IO circuit comprising a read amplifier and a write operations driver circuit. The pass-gate 14 is typically composed of a P type transistor 142 and an N type transistor 141, the gates of which are connected by the erase signal ERASE and by its complement, respectively.

Such a pass-gate 14 thus makes it possible to alternatively isolate the first line BLT when it is required to make an erase, or to connect this bit line BLT to the element of the peripheral IO circuit during normal operation of the memory plane, depending on the state of the erase signal ERASE.

The pass-gate 16 located between the second bit line BLF and the element of the peripheral IO circuit, is typically composed of a P type transistor 162 and an N type transistor 161, the gates of which are controlled by the erase signal ERASE and by the complement (inverse) of this signal, respectively.

During normal operation of the memory plane, the cells are powered by a power supply circuit, typically in the form of a grid, capable of outputting a power supply potential in this example equal to VDD, to a power supply line 18 shared by a plurality of cells C₁₁, . . . C_{N1}. The power supply potential VDD is used particularly to bias the transistors of the inverters INV1, INV2 of cells C₁₁, . . . C_{N1}. The power supply line 18 is also named the virtual power supply line and may be disconnected from the power supply grid during an erase. The erase circuit can trigger disconnection from the power supply line 18, or can put it in high impedance or leave it floating.

According to one particularly advantageous embodiment, it is also planned to temporarily disconnect the memory plane (matrix) from its power supply circuit as soon as the erase operation is started, to facilitate fast evacuation of electrical charges and consequently enable fast erase of the memory while limiting consumption.

In the particular example embodiment illustrated on FIG. 2, the power supply line 18 provided to apply a power supply voltage VDD is shared between the cells C₁₁ . . . C_{N1} in the same column COL₁ of cells. During the erase process, the power supply line 18 is disconnected or is put in high impedance or left floating, and the power supply voltage VDD is no longer applied to the cells C₁₁, . . . C_{N1} in column COL₁ of cells.

The erase circuit is also advantageously provided with a switch element 19 controlled by the erase signal ERASE and configured to disconnect said power supply line 18 from said power supply circuit (or grid), after the erase signal ERASE is received.

The switch element 19 may be in the form of a transistor 191, of the PMOS type in the example illustrated, that is located between the power supply circuit at voltage VDD and the power supply line 18, the gate of which can receive the erase signal ERASE. In the particular example illustrated, the switching transistor 191 is located at the base of the column, with a gate connected to the different switching elements 12, 14, 16 described above

According to one variant layout (not shown), it is also possible to have a biasing line that can route the power supply potential VDD and shared by the cells of the same line (horizontal row) LINk of cells. In this case, a different layout of the switching element 19 is provided, that may be located at one end of this line LINk, between this line and the power supply circuit.

The erase circuit is advantageously also provided with means of simultaneously selecting cell lines, controlled by the erase signal ERASE, and configured to simultaneously select several cell lines and preferably all cells in the matrix plane, so that several cell lines and preferably all cell lines in the matrix plane can be erased simultaneously. These selection means are integrated into a line decoder RDEC of the memory plane and are adapted to simultaneously activate the different word lines WL associated with the different lines LIN₁, . . . , LIN_{N} (horizontal rows) of cells, and thus access cells controlled by these different word lines.

In the example embodiment illustrated on FIG. 2, and so that all word lines WL can be activated simultaneously, a line 21 is added to the line decoder RDEC associated with the memory plane, to route the erase signal ERASE. The decoder RDEC is typically a 1 among N decoder in which N is the number of lines in the memory plane. A transistor 22, the gate of which is connected to line 21, is also added to each stage of the line decoder RDEC associated with a line of cells in the matrix. This transistor 22 is thus designed to connect the line 21 to this stage when the erase signal ERASE is received by the line 21. The transistor 22, the gate of which is controlled by the erase signal ERASE, is connected to a logic gate DLG of a decoder stage and to the input of a buffer circuit BUF located at the output from the line decoder RDEC. The buffer circuit BUF is typically formed from at least one inverter or a succession of inverters in series. In this example, the logic gates DLG are implemented in dynamic logic.

Each can thus be provided with a precharge transistor Tp and an evaluation transistor Te controlled by a clock signal. The transistor 22 comprises a drain connected to the precharge transistor Tp of the dynamic gate and comprises a source connected to the evaluation transistor.

The erase signal ERASE and its complement may be output by a controller CTL, in other words a memory control peripheral logic circuit that is configured particularly to manage read and write processes depending on a sequence of states. The structure of the controller CTL may be conventional and in particular additional means or a circuit can also be provided to receive the erase signal ERASE and to apply this ERASE signal and its complement to the switching element 12 designed to short circuit bit lines BLT et BLF, and to switching elements 14, 16 specifically designed to isolate bits when they are short circuited, and to the switching element 19 provided to isolate cells from their power supply circuit, respectively. These additional means may comprise an inverter 31.

The controller CTL is also provided with means 35 of outputting this clock signal to line decoders and making a logical OR between the erase signal ERASE and an internal clock signal CLKint generated internally by the controller. The signal CLKint is typically in the form of a pulse with a duration that controls the duration of the mode (read or write) in which a selected circuit is placed.

When the ERASE signal is sent, all word lines WL in the matrix are activated simultaneously, regardless of their state before this operation.

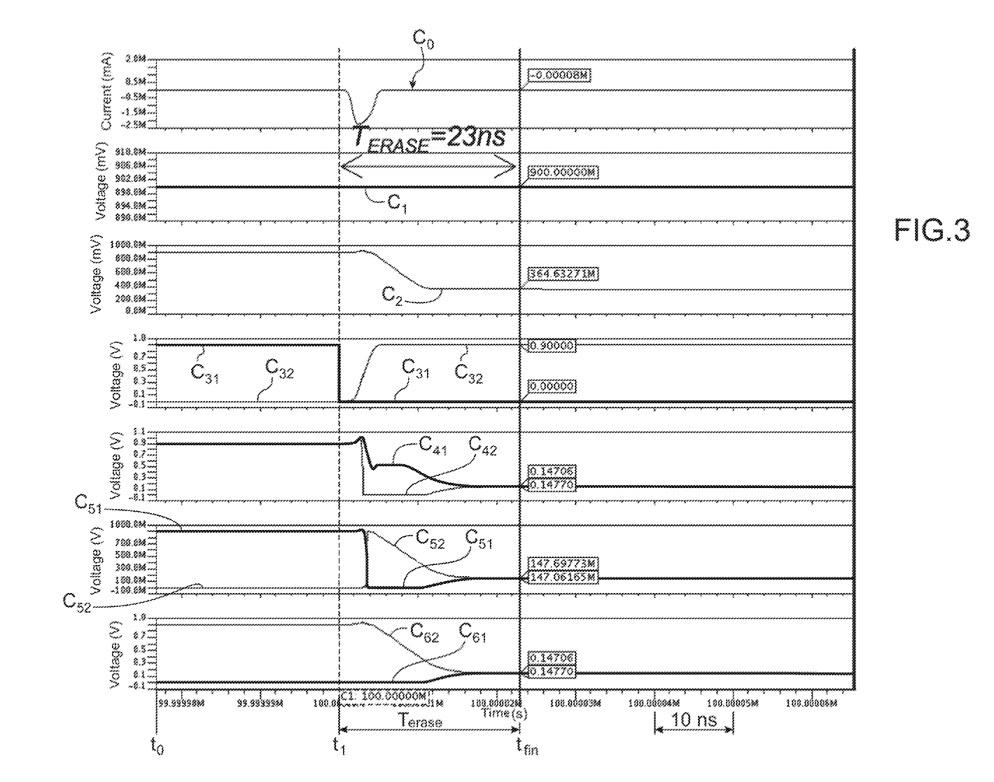

FIG. 3 shows an example of a simulation time diagram representative of the erase process implemented by a fast erase circuit of the type described above, with a power supply voltage VDD of the order of 0.9 V, SS (“Slow”-“Slow”) type cells formed from “slow” type switching NMOS and PMOS transistors, bit lines with a capacitance approximately the same as the capacitance of the power supply line 18 at Vdd, and an operating temperature of −40° C. In this example, the cell columns comprise 512 cells with 511 cells storing “1” logical information and one cell storing a “0” logical information. Therefore the simulation is done under conditions of temperature, biasing potential, transistor speed and nature of stored logical information that are particularly difficult for a fast erase. However, the erase time obtained in this example may be of the order of several tens of nanoseconds, for example of the order of 20 ns.

On the time diagram, the curves C0 and C2 are representative of a current taken from the power supply line 18 and the power supply potential output by this line 18, to the cells in a column, while curve C1 is representative of the voltage VDD output by the power supply circuit.

Curves C31 and C32 are representative of the signal taken at the input to inverter BUF and at the output from this inverter and therefore from the line decoder RDEC, respectively.

Curves C41 and C42 are representative of the signal taken on bit lines BLT and BLF respectively, the bit line BLF in this example being precharged to VDD.

Curves C51 and C52 are representative of signals taken on the first node T and on the second node F respectively of a cell in which the ‘0’ logical information has been written, while the other cells in the same column are equal to ‘1’.

Curves C61 and C62 are representative of signals taken on the first node T and on the second node F respectively of a cell in which the ‘1’ logical information has been stored.

Before the erase, between t0 and t1, the power supply circuit is connected to the power supply line 18 that outputs the potential VDD to the cells. The word lines are deactivated, while the bit lines BLT and BLF are precharged to potential VDD.

The erase operation begins at time t1, starting from which the cells are selected by activation of word lines (curve C41), bit lines bits BLT and BLF are short circuited and the power supply line at potential VDD is simply disconnected from the memory power supply circuit or power supply grid.

The erase time considered is the duration between a time t1 and a time tfin so that the storage nodes of the last of the 512 cells is at the same potential.

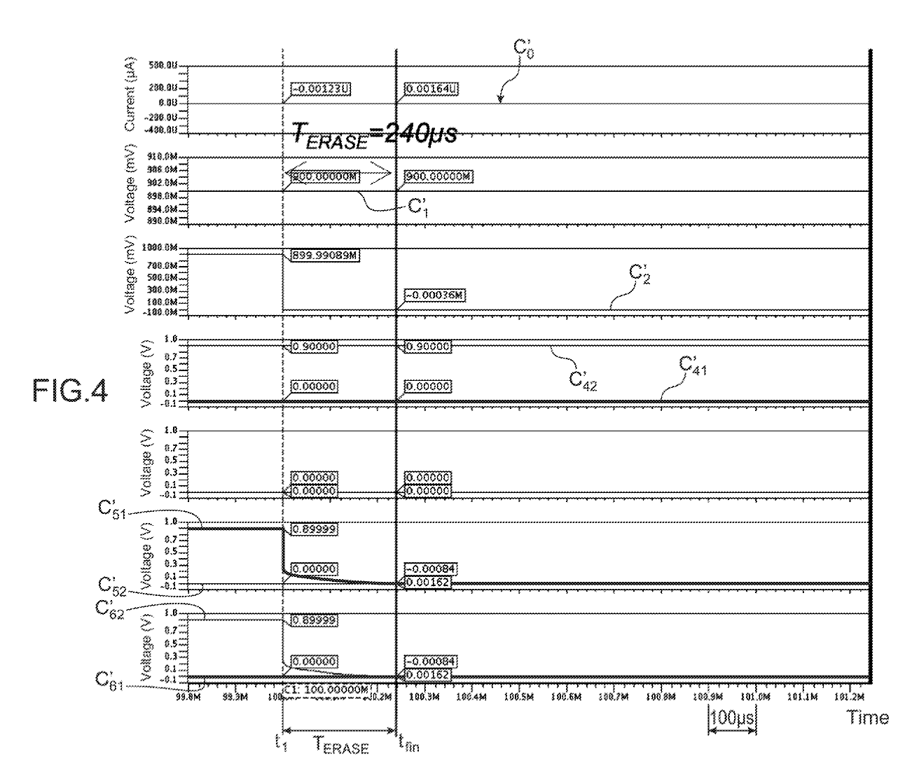

For comparison, FIG. 4 gives a time diagram for chaining of the phases of an erase operation used on identical cells and taken under the same conditions (temperature, power supply, speed of transistors, etc.) as those described with reference to FIG. 3, but with a different erase process.

This time, the erase operation simulation is made without simultaneous activation of word lines WL and simply by connecting the power supply to the ground. In this case, simultaneous grounding is achieved practically instantaneously, to obtain the best case for this erase mode. Curves C′0, C′1, C′2, C′31, C′32, C′41, C′42, C′51, C′52, C′61, C′62 are representative of the same types of signals as curves C0, C1, C2, C31, C32, C41, C42, C51, C52, C61, C62 given on FIG. 3.

Thus, it is observed that in the case of operating conditions similar to those previously given with reference to FIG. 3, the time required so that information contained in a cell (placed under the same conditions as the condition determining the end of the erase process) are completely lost or erased, is of the order of several hundred microseconds, for example of the order of 200 μs. Therefore the erase duration is much longer.

Activation of each cell is and short circuiting of the bit lines as implemented by the erase circuit described previously can thus evacuate electrical charges more efficiently and more quickly than simply grounding the power supply line 18.

A block 200 of the erase circuit receiving the erase signal ERASE described above at its input IN can be designed to output a detection of the end of erase operation ERASE_END signal at its output OUT marking the end of the erase operation described above. Such an end of erase operation signal ERASE_END can assure that the erase operation has actually been done. Such a signal can be particularly useful to determine when the memory is ready for a new cycle, and so that it can thus be reused more quickly. Such a signal is particularly useful when the memory comprises a modulable power supply VDD. A change in the power supply voltage applied to the cells can induce a variable erase duration. Therefore it is particularly advantageous in this case to have an end of erase detection means.

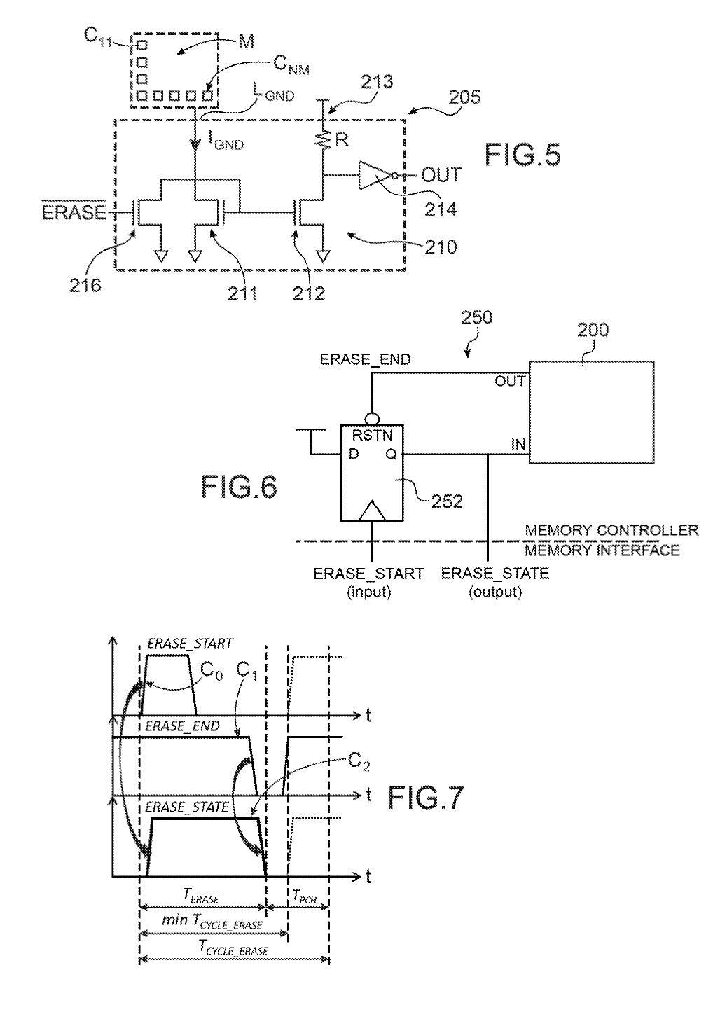

In the example embodiment illustrated on FIG. 5, a stage 205 of the block 200 uses a current I_{LGND} originating from the low power supply line, in particular the ground line L_{GND} of the matrix M of cells C₁₁, . . . , C_{NM}, to produce the end of erase signal ERASE_END when the current I_{LGND} output from this low power supply line drops below a threshold.

As indicated above, during the erase operation controlled by the ERASE signal being put in a given state, the matrix M is disconnected from its power supply. This disconnection provoking a discharge of the cells and a current I_{LGND} generated at a ground line L_{GND} connected to the cells is produced. The current I_{LGND} dropping below a threshold can be detected for example by means of a current detection amplifier 210, provided with transistors 211, 212 forming a current mirror. A means 213 forming a current detection resistance R is used to convert the current I_{GND} in the low power supply line into a voltage, that is output to the input of an inverter 214, the output OUT of which triggers production of an end of erase signal ERASE_END, through a state change.

Production of this end of erase signal ERASE_END triggers a state change of the ERASE signal transmitted to the input IN of the block 200 of the erase circuit and that controls the lines decoder RDEC and the switching elements 12, 14, 16 and the switch 19.

To enable this state change, a state control stage 250 of the erase signal ERASE can be provided, equipped with a flip flop D 252, the input D of which in this example is forced to a level ‘1’ and in which the output state determines the state of the erase signal ERASE, as shown on FIG. 6.

As illustrated on the time diagram in FIG. 7, a front (in this example a rising front on curve C₀), of a start erase signal ERASE_START originating from the input output interface or a memory controller triggers a first state change of the erase signal ERASE. This state change is used to control the different elements, in particular the line decoder R_DEC, the switch element 12, the switch element 14, the switching element 19 that participate in the erase operation.

It is only when the signal applied on the asynchronous reset input of the flip flop 252 and that originates from the output OUT of the block 200 producing the end of erase detection signal (falling front on curve C₁) changes state that the erase signal ERASE is once again able to change state (falling front on curve C₂) which in particular leads to a stop of the simultaneous selection of a set of cell lines, and to disconnection of either bit line BL_{T} or BL_{F}.

On this time diagram, Tₑᵣₐₛₑ represents the duration of the erase operation and T_{PCH} represents the duration necessary to precharge bit lines once they have been disconnected from each other and that is done so as to prepare the device for another operating cycle.

1. Static random access memory device comprising a memory matrix provided with at least one column formed from a plurality of SRAM memory cells, each of said cells comprising:
a first logical information storage node and a second complementary logical information storage node,
a first access transistor to the first storage node and a second access transistor to the second storage node, the first access transistor and the second access transistor being connected to a first bit line and a second bit line respectively, the first bit line and the second bit line being shared by said cells of said column,
the device also comprising an erase memory circuit configured to force conduction of the access transistors of said cells and to connect said first bit line and said second bit line to each other, following reception of an erase signal.

2. Device according to claim 1, the erase circuit being provided with at least one first switching element, particularly a first pass-gate, configured to alternately connect together and to disconnect the first bit line and the second bit line, the switching element being controlled by the erase signal and being arranged between one end of said cell column and a portion of a circuit peripheral to said matrix, said peripheral circuit being provided with a read amplifier and a read and/or write operations driver.

3. Device according to claim 2, the erase circuit also being provided with other switching elements, and particularly a second pass-gate and a third pass-gate, controlled by the erase signal, and configured to disconnect the first bit line and the second bit line respectively from said portion of peripheral circuit, following reception of the erase signal.

4. Device according to claim 1, comprising one or several power supply lines to output a power supply potential to said plurality of SRAM memory cells, said erase circuit being configured to leave one or several power supply lines floating or to put them in high impedance, following reception of the erase signal.

5. Device according to claim 1, wherein the memory matrix is powered by a power supply circuit capable of outputting a power supply potential to at least one power supply line shared by a plurality of data cells, said erase circuit also being provided with a switch element controlled by the erase signal and configured to disconnect said power supply line from said power supply circuit, after an erase signal is received.

6. Device according to claim 5, said plurality of data cells belonging to said column.

7. Device according to claim 1, wherein the memory matrix is associated with a peripheral controller for management of the read and write process, the erase circuit also comprising means or a circuit element, integrated into said controller and provided with an inverter, the integrated means or circuit element being configured to apply the erase signal and a signal complementary to said erase signal.

8. Device according to claim 1, wherein the matrix is also arranged in rows of one or several SRAM cells, and in which a plurality of word lines is connected to said plurality of SRAM memory cells of said column respectively, each word line when it is activated being used to select the memory cell(s) of a given row of SRAM cells among said rows of SRAM cells, the erase circuit also comprising means of simultaneously activating said word lines to simultaneously activate word lines, so as to make a simultaneous selection of said rows of SRAM cells.

9. Device according to claim 8, wherein the means of activating the word line comprise a plurality of transistors arranged at different stages of a line decoder, said transistors having a gate electrode controlled by the erase signal.

10. Device according to claim 9, wherein the line decoder is equipped with dynamic logic gates and wherein the memory matrix is associated with a peripheral controller for management of the read and write process, the erase circuit comprising means to output a dynamic logic gates dock signal and forming a logical OR between a clock signal internal to the line decoder and the erase signal.

11. Device according to claim 1, wherein the erase circuit is provided with an end of erase detection stage to generate an end of erase signal indicating the end of an erase operation performed by said erase circuit.

12. Device according to claim 11, wherein the end of erase detection stage is configured so as to:
detect when a current output from a low power supply line connected to said cells of the matrix drops below a threshold, and subsequent to this passage:
generate the end of erase signal.

13. Device according to claim 12, wherein the erase circuit also comprises a stage to control the state of the erase signal to modify the state of said erase signal following reception of said end of erase signal.
